(19) United States
(12) Patent Application Publication
(10) Pub. No.: US 2025/0280559 A1
(43) Pub. Date: Sep. 4, 2025

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Feng-Ming CHANG, Taitung City (TW); Chi-Hsin CHANG, New Taipei City (TW); Wei-Chi SONG, Chiayi City (TW); Ming-Che CHEN, Hsinchu City (TW); Kao-Ting LAI, Hsinchu City (TW)

(73) Assignee: Taiwan Semiconductor Manufacturing Company, Ltd., Hsinchu (TW)

(21) Appl. No.: 18/593,247

(22) Filed: Mar. 1, 2024

(51) Int. Cl. H01L 29/775; H01L 29/06; H01L 29/08; H01L 29/417; H01L 29/423; H01L 29/66

(52) U.S. Cl. CPC H10D 30/43; H10D 30/014; H10D 30/6729; H10D 30/6735; H10D 62/121; H10D 62/151; H10D 64/017; H10D 64/018

(57) ABSTRACT

A semiconductor structure includes a substrate, nanostructures, a dielectric layer, source/drain features, a gate structure, and inner spacers. The nanostructures are over the substrate and spaced apart from each other in a Z-direction. The dielectric layer is between and in contact with the nanostructures and the substrate in the Z-direction. The source/drain features are electrically connected to and on opposite sides of the nanostructures in an X-direction. The gate structure extends in a Y-direction and wraps around the nanostructures. The inner spacers are between the nanostructures and the substrate in the Z-direction. The inner spacers are on opposite sides of the dielectric layer in the X-direction.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been incorporated into memory devices (including, for example, static random-access memory, or SRAM, cells) and core devices (including, for example, standard logic, or STD, cells) to reduce chip footprint while maintaining reasonable processing margins.

However, as GAA devices continue to be scaled down, conventional methods for manufacturing GAA devices may experience challenges. Accordingly, although existing technologies for fabricating GAA devices have been generally adequate for their intended purposes, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIGS. 2A, 2B, and 2C illustrate circuit schematics of various STD cells that can be implemented in the logic region of the IC chip of FIG. 1 in accordance with some embodiments of the present disclosure.

FIGS. 3 and 4 illustrate circuit schematics of a static random access memory (SRAM) cell that can be implemented in the memory region of the IC chip of FIG. 1, in accordance with some embodiments of the present disclosure.

FIGS. 5, 6, 7, and 8 are perspective views of a workpiece at various fabrication stages, in accordance with some embodiments of the present disclosure.

FIGS. 9A, 10A, 11A, 12A, 13A, 14A, 15A, 16A, 17A, and 18A are X-Z cross-sectional views of the workpiece at various fabrication stages along a line A-A′ of FIG. 8, in accordance with some embodiments of the present disclosure.

FIGS. 9B, 10B, 11B, 12B, 13B, 14B, 15B, 16B, 17B, and 18B are Y-Z cross-sectional views of the workpiece at various fabrication stages along a line B-B′ of FIG. 8, in accordance with some embodiments of the present disclosure.

FIG. 19 is an X-Z cross-sectional view of the workpiece at the fabrication stage, in accordance with some alternative embodiments of the present disclosure.

FIG. 20 is an X-Z cross-sectional view of the workpiece at the fabrication stage, in accordance with some alternative embodiments of the present disclosure.

FIG. 21 is an X-Z cross-sectional view of the workpiece at the fabrication stage, in accordance with some alternative embodiments of the present disclosure.

FIG. 22 is an X-Z cross-sectional view of the workpiece at the fabrication stage, in accordance with some alternative embodiments of the present disclosure.

FIG. 23 is a partial enlarged cross-sectional view of the workpiece at the fabrication stage in a dashed box of FIG. 18A, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications. While existing technologies for fabricating GAA transistors have been generally adequate for their intended applications, they have not been entirely satisfactory in all aspects.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including GAA transistors with dielectric layer between the nanostructures and the substrate, such that the parasitic capacitance between the gate structure and the substrate are reduced, thereby improving the performance of the GAA transistors. The details of the structure and manufacturing methods of the present disclosure are described below in conjunction with the accompanying drawings, which illustrate the process of making GAA transistors, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

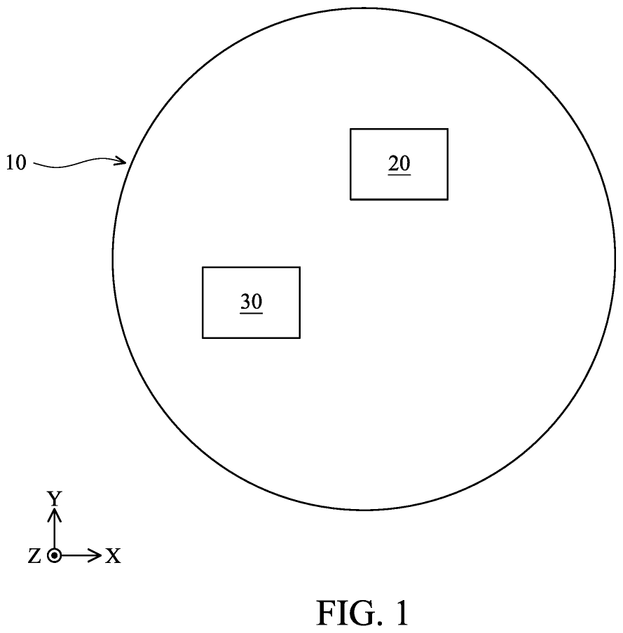

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, P-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or a combination thereof.

The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, the IC chip 10 includes a memory region 20 and a logic region 30.

The memory region 20 can include an array of memory cells, each of which includes transistors and interconnection structures (also referred to as routing structures) that combine to provide a storage device and/or a storage function, such as a flip flop, a latch, other suitable memory devices, or combinations thereof. In some embodiments, the memory region 20 is configured with static random-access memory (SRAM) cells, dynamic random-access memory (DRAM) cells, non-volatile random-access memory (NVRAM) cells, flash memory cells, other suitable memory cells, or combinations thereof.

The logic region 30 can include an array of circuit cells having various logic cells or standard (STD) cells. The logic cells or STD cells may include transistors and interconnection structures that combine to provide a logic device and/or a logic function, such as an inverter, an AND, an NAND, an OR, an NOR, a NOT, an XOR, an XNOR, other suitable logic devices, or combinations thereof. FIG. 1 has been simplified for the sake of clarity to better understand the inventive concepts of the present disclosure. Additional features can be added in IC chip 10, and some of the features described herein can be replaced, modified, or eliminated in other embodiments of the IC chip 10.

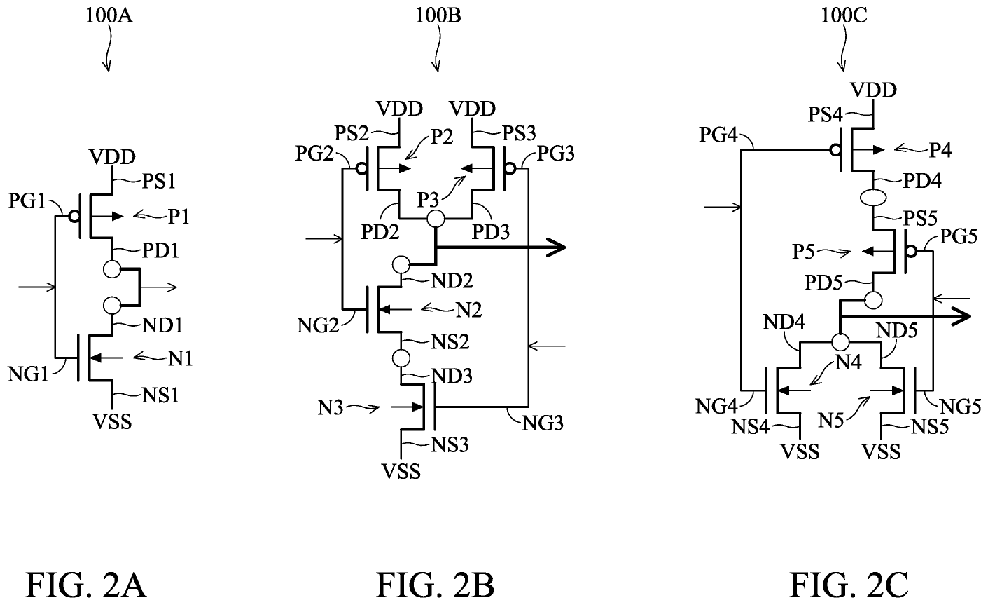

FIGS. 2A to 2E are circuit schematics of various STD cells in the array of circuit cells in the logic region 30 of the IC chip 10, in accordance with some embodiments of the present disclosure.

FIG. 2A shows an inverter 100A including an N-type transistor N1 and a P-type transistor P1. The N-type transistor N1 includes a source terminal NS1, a drain terminal ND1, and a gate terminal NG1, and the P-type transistor P1 includes a source terminal PS1, a drain terminal PD1, and a gate terminal PG1.

As shown in FIG. 2A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B shows a NAND (also referred to as a NAND logic gate, a NAND device or a NAND cell) 100B including N-type transistors N2, N3 and P-type transistors P2, P3. The N-type transistor N2 includes a source terminal NS2, a drain terminal ND2, and a gate terminal NG2, and the N-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B, and the gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as a “common drain.” The source terminals PS2 and PS3 are coupled to the VDD voltage. The source terminal NS3 is coupled to VSS voltage (or a ground voltage). The source terminal NS2 and drain terminal ND3 are coupled with each other.

FIG. 2C shows a NOR (also referred to as a NOR logic gate, a NOR device or a NOR cell) 100C including N-type transistors N4, N5 and P-type transistors P4, P5. The N-type transistor N4 includes a source terminal NS4, a drain terminal ND4, and a gate terminal NG4, and the N-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage (or a ground voltage). The source terminal PS5 and drain terminal PD4 are coupled with each other.

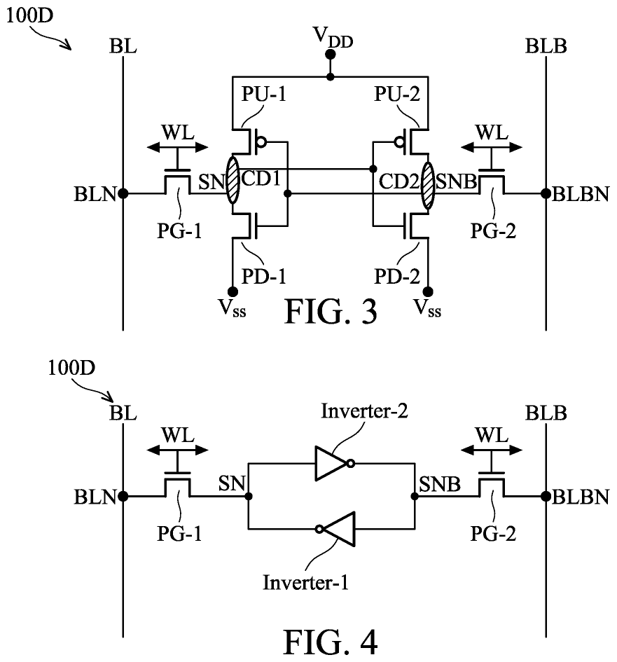

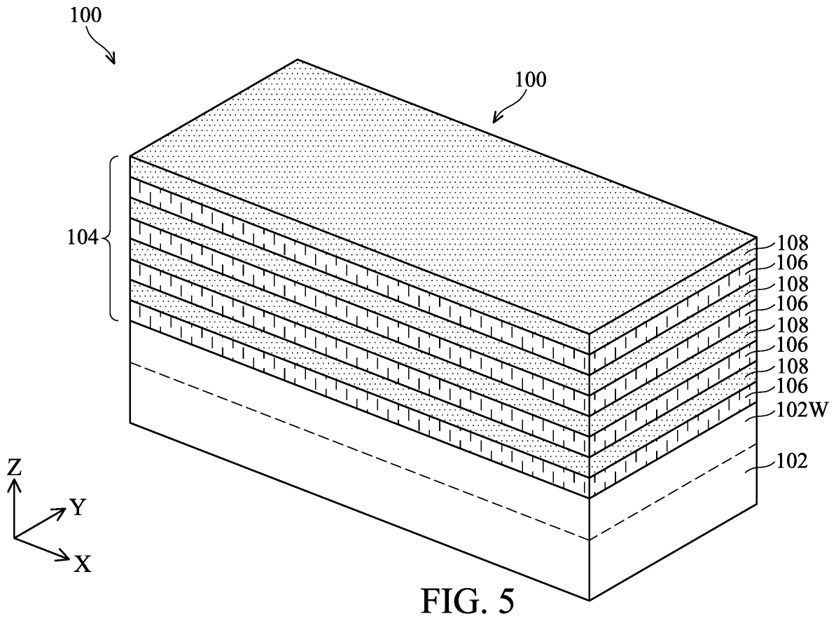

FIGS. 3 and 4 are circuit diagrams of an SRAM circuit that can be implemented in an SRAM cell of an array in the memory region 20 of FIG. 1, in accordance with some embodiments of the present disclosure. The circuit diagram of SRAM cell is merely exemplary, and in some embodiments, each of SRAM cells in the array is configured with an SRAM circuit similar to the SRAM cells 100D as shown in FIGS. 2 and 3. For example, each of SRAM cells has a storage portion that includes a cross-coupled pair of inverters (also referred to as a latch), such as an Inverter-1 and an Inverter-2. Inverter-1 includes pull-up transistor PU-1 and pull-down transistor PD-1, and Inverter-2 includes pull-up transistor PU-2 and pull-down transistor PD-2. Pass-gate transistor PG-1 is connected to an output of Inverter-1 and an input of Inveter-2, and pass-gate transistor PG-2 is connected to an output of Inverter-2 and an input of Inverter-1.

In operation, pass-gate transistor PG-1 and pass-gate transistor PG-2 provide access to the storage portion of their respective SRAM cell (i.e., Inverter-1 and Invereter-2) and can also be referred to as access transistors of their respective SRAM cell. Each of SRAM cells is connected to and powered through a first power supply voltage, such as a positive power supply voltage, and a second power supply voltage, such as a ground voltage or a reference voltage (which can be an electrical ground).

A gate of pull-up transistor PU-1 interposes a source, which is electrically coupled to the first power supply voltage via a voltage node (or voltage source) VDD, and a first common drain (CD1) (i.e., a drain of pull-up transistor PU-1 and a drain of pull-down transistor PD-1). A gate of pull-down transistor PD-1 interposes a source, which is electrically coupled to the second power supply voltage via a voltage node (or voltage source) Vss, and the first common drain.

A gate of pull-up transistor PU-2 interposes a source, which is electrically coupled to the first power supply voltage via voltage node VDD, and a second common drain (CD-2) (i.e., a drain of pull-up transistor PU-2 and a drain of pull-down transistor PD-2). A gate of pull-down transistor PD-2 interposes a source, which is electrically coupled to the second power supply voltage via voltage node Vss, and the second common drain.

The first common drain provides a storage node SN that stores data in true form, and the second common drain provides a storage node SNB that stores data in complementary form, or vice versa, in some embodiments. The gate of pull-up transistor PU1 and the gate of pull-down transistor PD-1 are coupled together and to the second common drain SD2, and the gate of pull-up transistor PU-2 and the gate of pull-down transistor PD-2 are coupled together and to the first common drain SD1.

A gate of pass-gate transistor PG-1 interposes a drain connected to a bit line node BLN, which is electrically coupled to a bit line BL, and a source, which is electrically coupled to the first common drain SD1. A gate of pass-gate transistor PG-2 interposes a drain connected to a complementary bit line node BLBN, which is electrically coupled to a complementary bit line BLB, and a source, which is electrically coupled to the second common drain SD2.

Gates of pass-gate transistors PG-1, PG-2 are connected to and controlled by a word line WL, which allows selection of a respective SRAM cell for reading and/or writing. In some embodiments, pass-gate transistors PG-1, PG-2 provide access to storage nodes SN, SNB, respectively, each of which can store a bit (e.g., a logical 0 or a logical 1), during read operations and/or write operations. For example, pass-gate transistors PG-1, PG-2 couple storage nodes SN, SNB, respectively, to bit line BL and bit line bar BLB in response to voltage applied to the gates of the pass-gate transistors PG-1, PG-2 by the word line WL. In some embodiments, SRAM cells are single-port SRAMs. In some embodiments, SRAM cells are configured as multi-port SRAMs, such as dual-port SRAMs, and/or with more or less transistors than depicted, such as 8T SRAMs.

FIGS. 3 and 4 have been simplified for the sake of clarity to better understand the inventive concepts of the present disclosure. Additional features can be added in the SRAM circuits of FIGS. 3 and 4, and some of the features described herein can be replaced, modified, or eliminated in other embodiments of the SRAM circuits of FIGS. 3 and 4.

Each of the circuit cells and the SRAM cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, exemplary GAA transistors for the circuit cells and the SRAM cells discussed above are illustrated and described in below. More specifically, the manufacturing method and the structure of GAA transistors with improved dielectric layer between nanostructures and substrate for the circuit cells and the SRAM cells discussed above are illustrated and described in below. However, it should be understood that the application should not be limited to a particular type of device, except as specifically claimed.

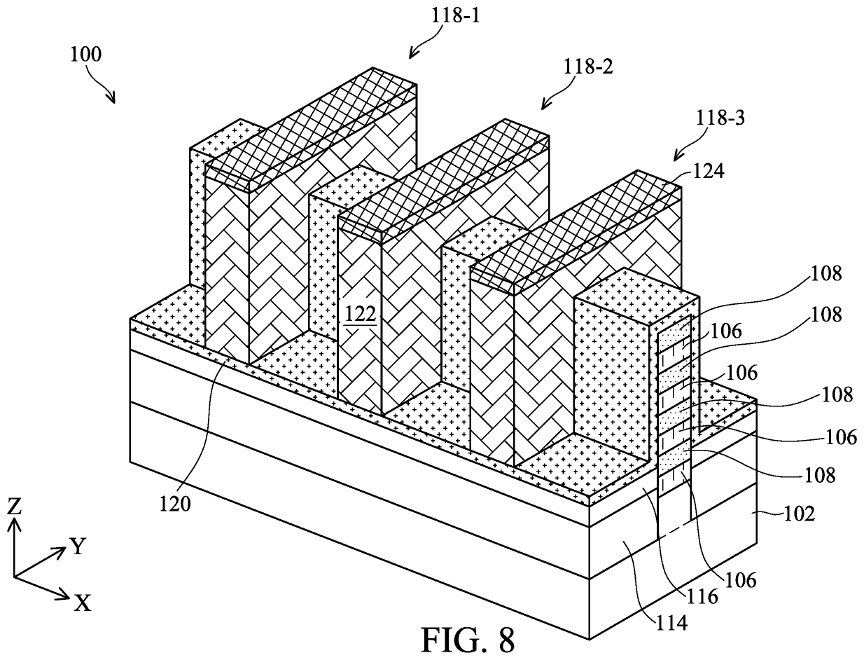

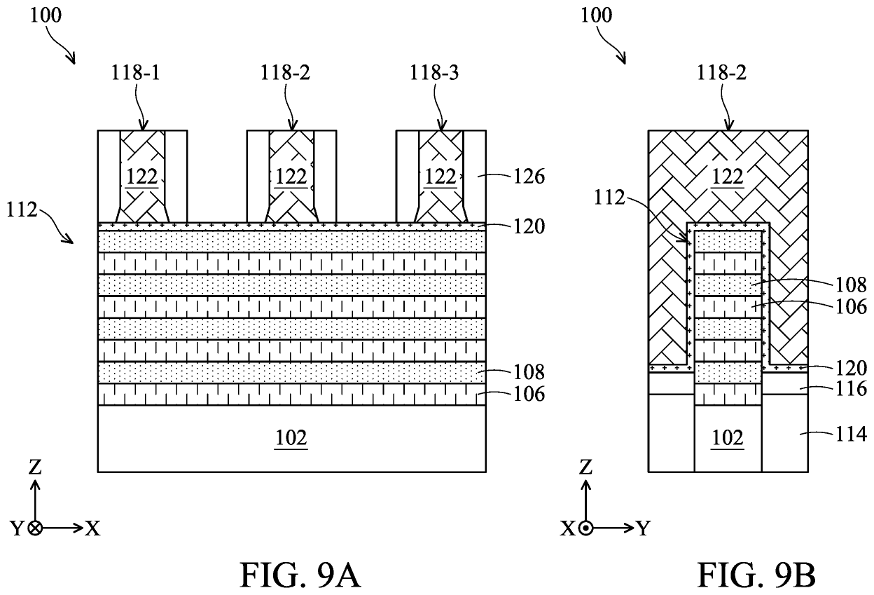

FIGS. 5, 6, 7, and 8 are perspective views of a workpiece 100 at various fabrication stages, in accordance with some embodiments of the present disclosure. FIGS. 9A, 10A, 11A, 12A, 13A, 14A, 15A, 16A, 17A, and 18A are X-Z cross-sectional views of the workpiece 100 at various fabrication stages along a line A-A′ of FIG. 8, in accordance with some embodiments of the present disclosure. FIGS. 9B, 10B, 11B, 12B, 13B, 14B, 15B, 16B, 17B, and 18B are Y-Z cross-sectional views of the workpiece 100 at various fabrication stages along a line B-B′ of FIG. 8, in accordance with some embodiments of the present disclosure.

Referring to FIG. 5, the workpiece 100 is provided. The workpiece 100 may include a substrate 102 and a stack 104 over the substrate 102. In some embodiments, the substrate 102 contains a semiconductor material, such as bulk silicon (Si). Alternatively or additionally, in some other embodiments, another elementary semiconductor, such as germanium (Ge) in a crystalline structure, may also be included in the substrate 102. The substrate 102 may also include a compound semiconductor, such as silicon germanium (SiGe) or a III-V semiconductor material. Example III-V semiconductor materials may include silicon carbide (SiC), indium arsenide (InAs), indium antimonide (InSb), indium phosphide (InP), gallium arsenide (GaAs), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and/or indium gallium arsenide (InGaAs), or combinations thereof. The substrate 102 may also include an insulating layer, such as a silicon oxide layer, to have a semiconductor-on-insulator substrate, such as Si-on-insulator (SOI), SiGe-on-insulator (SGOI), Ge-on-insulator (GOI) substrates.

In some embodiments, the substrate 102 may include various doped regions configured according to design requirements of GAA transistors. In some embodiments, the substrate 102 may include a doped region 102W (also referred to as a well region). The doped region 102W may be an n-type doped region (also referred to as an n-well) or a p-type doped region (also referred to as a p-well), and the n-type doped region is configured for a p-type metal-oxide-semiconductor (PMOS) transistor and the p-type doped region is configured for an n-type MOS (NMOS) transistor. N-type doped region is doped with n-type dopants, such as phosphorus, arsenic, other n-type dopant, or combinations thereof. P-type doped region is doped with p-type dopants, such as boron (for example, BF₂), indium, other p-type dopant, or combinations thereof.

In the present embodiment, the substrate 102 shows one doped region 102W. In other embodiments, substrate 102 may include multiple doped regions formed with a combination of p-type dopants and n-type dopants. An ion implantation process, a diffusion process, and/or other suitable doping process can be performed to form the various doped regions. In some embodiments, n-type doped region has an n-type dopant concentration of about 5×10¹⁶ cm⁻³ to about 5×10¹⁹ cm⁻³, and p-type doped region has a p-type dopant concentration of about 5×10¹⁶ cm⁻³ to about 5×10¹⁹ cm⁻³. Because the workpiece 100 will be fabricated into a semiconductor structure 100 upon conclusion of the fabrication processes, the workpiece 100 may be referred to as the semiconductor structure 100 as the context requires.

The stack 104 includes semiconductor layers 106 and 108, and the semiconductor layers 106 and 108 are alternatingly stacked in the Z-direction. The semiconductor layers 106 and the semiconductor layers 108 may have different semiconductor compositions. In some embodiments, semiconductor layers 106 are formed of silicon germanium (SiGe) and the semiconductor layers 108 are formed of silicon (Si). In these embodiments, the additional germanium content in the semiconductor layers 106 allow selective removal or recess of the semiconductor layers 106 without substantial damages to the semiconductor layers 108, so that the semiconductor layers 106 are also referred to as sacrificial layers.

In some embodiments, the semiconductor layers 106 and 108 are epitaxially grown over (on) the substrate 102 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 106 and the semiconductor layers 108 are deposited alternatingly, one-after-another, to form the stack 104.

It should be noted that four (4) layers of the semiconductor layers 106 and four (4) layers of the semiconductor layers 108 are alternately and vertically arranged (or stacked) as shown in FIG. 5, which are for illustrative purposes only and not intended to be limiting beyond what is specifically recited in the claims. The number of layers depends on the desired number of channels members for the semiconductor device. In some embodiments, there may be from 3 to 10 semiconductor layers 106 alternating with 3 to 10 semiconductor layers 108 in the stack 104.

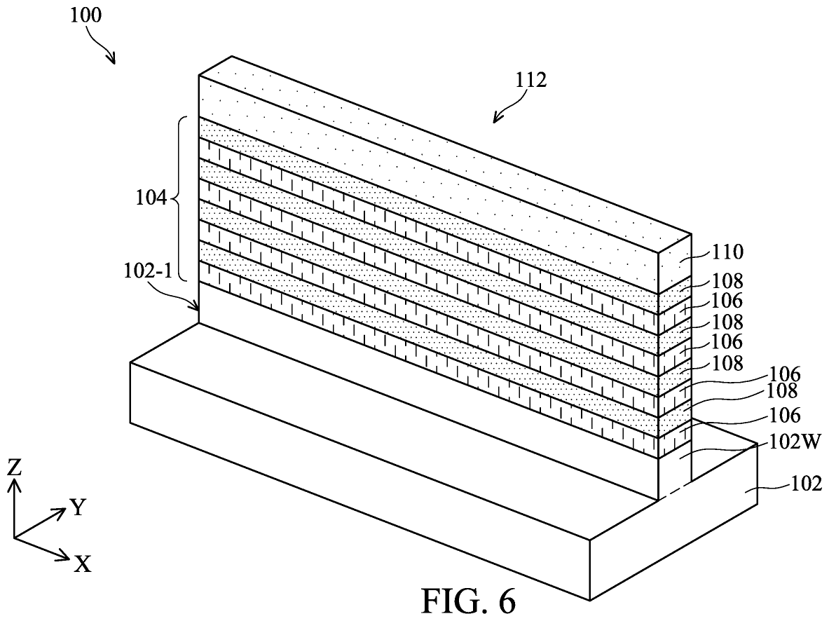

Referring to FIG. 6, the substrate 102 and the stack 104 are then patterned to form a fin 112 over the substrate 102. For patterning purposes, the workpiece 100 may also include a hard mask layer 110 over the stack 104 before the patterning of the substrate 102 and the stack 104. The hard mask layer 110 may be a single layer or a multi-layer. In some embodiments, the hard mask layer 110 is a single layer and includes a silicon germanium layer. In some embodiments, the hard mask layer 110 is a multi-layer and includes a silicon nitride layer and a silicon oxide layer over the silicon nitride layer. In some other embodiments, the hard mask layer 110 is a multi-layer and includes a silicon germanium layer and a silicon layer over the silicon germanium layer.

As shown in FIG. 6, the fin 112 includes a base fin 102-1 formed from a portion of the substrate 102 and a stack portion formed from the stack 104 over the base portion. In some aspects, the base fin 102-1 protrudes from the substrate 102. The fin 112 may include the semiconductor layers 106 and 108 alternating stacked in the Z-direction. The fin 112 extends lengthwise (e.g., longitudinally) in the X-direction, as shown in FIG. 6. Although one fin 112 is formed and shown herein, more fins may be formed, such as two or more fins.

The fins 112 may be patterned using suitable processes including double-patterning or multi-patterning processes. For example, in some embodiments, a material layer of the hard mask layer 110 is formed over the substrate 102 and patterned into the hard mask layer 110 using a photolithography process. One or more etching processes are then performed to etch the stack 104 and top portions of the substrate 102 not covered by the hard mask layer 110 to form the fin 112. The etching process may include dry etching, wet etching, reactive ion etching (RIE), and/or other suitable processes.

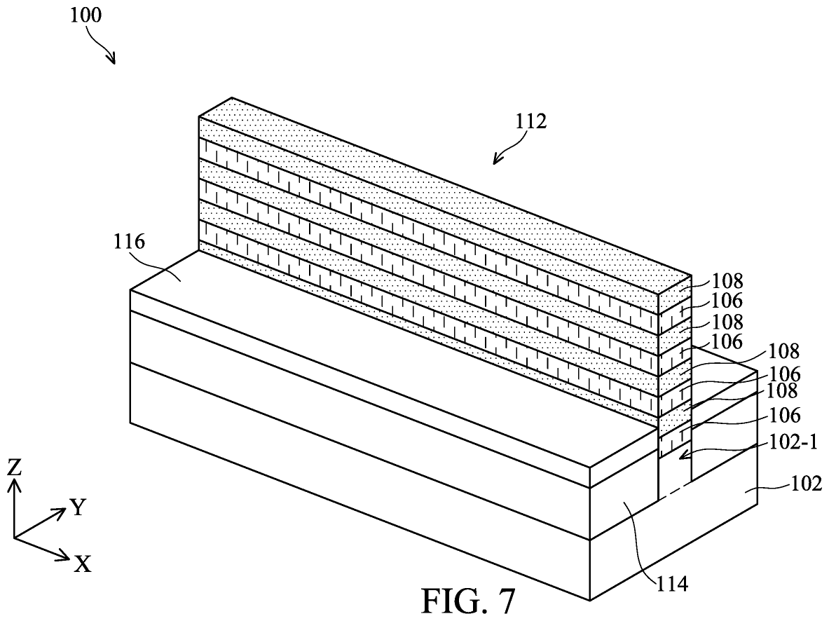

Referring to FIG. 7, isolation features 114 are formed over the substrate 102. More specifically, after the fin 112 is formed, the hard mask layer 110 over the fin 112 is removed and the isolation features 114 are then formed over the substrate 102. In some aspects, the isolation features 114 are formed around the fin 112. More specifically, the isolation features 114 are formed on opposite sides of the fin 112 (semiconductor layers 106 and 108) in the Y-direction. The isolation features 114 may be shallow trench isolation (STI) features that provide electrical isolation between the different GAA transistors, in accordance with some embodiments. As such, the isolation features 114 may also be referred to as STI features.

In some embodiments, a dielectric material for the isolation features 114 are first deposited over the workpiece 100. Specifically, the dielectric material is deposited and formed over the fin 112 and the substrate 102 to cover the fin 112 and the substrate 102. In some aspects, the dielectric material is formed to wrap around the fin 112. In some embodiments, the dielectric material may include silicon oxide, silicon nitride, silicon oxynitride, silicon carbide, borosilicate glass (BSG), phosphoric silicate glass (PSG), borophosphosilicate glass (BPSG), fluorine-doped silicate glass (FSG), a low-k dielectric (e.g., a carbon doped oxide, SiCOH), combinations thereof, and/or other suitable materials. In various embodiments, the dielectric material may be deposited by a CVD, a subatmospheric CVD (SACVD), a plasma-enhanced CVD (PECVD), a flowable CVD (FCVD), an ALD, a plasma-enhanced ALD (PEALD), spin-on coating, and/or other suitable process. The deposited dielectric material is then thinned and planarized, for example by a chemical mechanical polishing (CMP) process. The planarized dielectric material is further recessed by a dry etching process, a wet etching process, and/or a combination thereof to form the isolation features 114.

In some embodiments, the isolation features 114 may have a multi-layer structure such as a thermal oxide liner layer over the substrate 102 and a filling layer (e.g., silicon nitride or silicon oxide) over the thermal oxide liner layer. In some embodiments, before the formation of the isolation features 114, a liner layer may be conformally deposited over the substrate 102 using ALD or CVD. Furthermore, as shown in FIG. 7, the stack portion of the fin 112 rise above the isolation features 114 while the base fin 102-1 are surrounded by the isolation features 114. In some embodiments, a top surface (or a topmost surface) of the substrate 102 is lower than top surfaces of the isolation features 114. In other words, the top surfaces of the isolation features 114 are higher than the top surface (or the topmost surface) of the substrate 102. Therefore, the isolation features 114 are in contact with the semiconductor layers 106 of the fin 112 (or the bottommost semiconductor layer 106), as shown in FIG. 8

Still referring to FIG. 7, after the formation of the isolation features 114, hard mask layers 116 are formed over the isolation features 114. In some aspects, the hard mask layers 116 are also formed around the fin 112. In some embodiments, a dielectric material for the hard mask layers 116 are first deposited over the workpiece 100. Specifically, the dielectric material is deposited and formed over the fin 112 and the isolation features 114 to cover the fin 112 and the isolation features 114. In some aspects, the dielectric material is formed to wrap around the fin 112. In some embodiments, the dielectric material may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), combinations thereof, and/or other suitable materials. In other embodiments, the hard mask layers 116 may be or include high-k material for high selectivity to the features in sequent processes. The high-k material includes TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. In various embodiments, the dielectric material may be deposited by a CVD, a subatmospheric CVD (SACVD), a plasma-enhanced CVD (PECVD), a flowable CVD (FCVD), an ALD, a plasma-enhanced ALD (PEALD), spin-on coating, and/or other suitable process. The deposited dielectric material is then thinned and planarized, for example by a chemical mechanical polishing (CMP) process. The planarized dielectric material is further recessed by a dry etching process, a wet etching process, and/or a combination thereof to form the hard mask layers 116.

In some embodiments, top surfaces of the hard mask layers 116 are higher than the bottommost semiconductor layer 106. In some embodiments, the hard mask layers 116 are in contact with the semiconductor layers 106 and 108 (or the bottommost semiconductor layers 106 and 108) of the fin 112, as shown in FIG. 7. As such, the isolation features 114 and the hard mask layers 116 are fully cover sidewalls of the bottommost semiconductor layer 106 of the fin 112, in accordance with some embodiments.

Referring to FIG. 8, dummy gate structures 118-1 to 118-3 (may be collectively referred to as dummy gate structures 118) may be formed over the fin 112, the hard mask layers 116, the isolation feature 114, and the substrate 102. The dummy gate structures 118 may be configured to extend lengthwise in the Y-direction and wrap around a top surface and side surfaces of the fin 112, as shown in FIG. 8. In some embodiments, to form the dummy gate structures 118, a dummy interfacial material of a dummy interfacial layer 120 is first formed over fin 112 and over the hard mask layers 116. In some embodiments, the dummy interfacial layer 120 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material of a dummy gate electrode 122 is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof The dummy gate material and/or the dummy interfacial material may be formed by way of a thermal oxidation process and/or a deposition process (e.g., PVD, CVD, PECVD, and ALD).

Then, hard mask layers 124 are formed over the dummy gate material. In some embodiments, the hard mask layers 124 may be formed using photolithography and removal (e.g., etching) processes. In some embodiments, the hard mask layers 124 may include photoresist materials or hard mask materials. In some embodiments, each of the hard mask layers 124 may include multiple layers, such as a silicon nitride layer and a silicon oxide layer. After the formation of the hard mask layers 124, a removal process (e.g., etching) may be performed to remove portions of the dummy gate material for the dummy gate electrodes 122 that do not directly underlie the hard mask layers 124, thereby forming the dummy gate structures 118 each having the dummy interfacial layer 120, the dummy gate electrode 122, and the hard mask layer 124. It should be noted that the dummy interfacial material of the dummy interfacial layer 120 remains over fin 112 and over the hard mask layers 116 without being removed after the removal process for the dummy gate structures 118. As such, the dummy interfacial material is namely the dummy interfacial layer 120 shared by the dummy gate structures 118. The dummy interfacial layers 120 may also be referred to as dummy gate dielectrics. The dummy gate structures 118 may undergo a gate replacement process through subsequent processing to form metal gates, such as a high-k metal gate, as discussed in greater detail below. Furthermore, each of the dummy gate electrodes 122 of the dummy gate structures 118 may be formed with a tapered bottom portion (not shown in FIG. 8, may refer to FIG. 9A), in accordance with some embodiments.

FIG. 8 shows three dummy gate structures 118-1 to 118-3. In some embodiments, less or more dummy gate structures may be formed for one or more transistors sharing source/drain regions. In other embodiments, some dummy gate structures may also undergo a gate replacement process to form dielectric based gates that electrically isolate transistors formed by the dummy gate structure 118 from neighboring transistors or devices. For examples, dummy gate structures 118-1 and 118-3 may be replaced with dielectric material in sequent processes to form dielectric based gates to isolate resultant transistor formed from the dummy gate structure 118-2 from neighboring transistors or devices.

Referring to FIGS. 9A and 9B, after the formation of the dummy gate structures 118, the hard mask layers 124 are removed and gate spacers 126 are formed on the sidewalls of the dummy gate structures 118, over a top surface of the fin 112, and on sidewalls of the fin 112 (shown in FIG. 9B). More specifically, the gate spacers 126 are formed on opposite sidewalls of the fin 112 and formed on opposite sidewalls of the dummy gate structures 118, as shown in FIGS. 9A and 9B. The gate spacers 126 may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, or combinations thereof. The gate spacers 126 may include a single layer or a multi-layer structure. In some embodiments, the gate spacers 126 may be formed by conformally depositing a spacer layer (containing the dielectric material) over the hard mask layers 116, the isolation features 114, the fin 112, and dummy gate structures 118, followed by an anisotropic etching process to remove top portions of the spacer layer from the top surfaces of the hard mask layers 116, the isolation feature 114, the fin 112, and dummy gate structures 118. After the etching process, portions of the spacer layer on the sidewall surfaces of the fin 112 (not shown) and the dummy gate structures 118 substantially remain and become the gate spacers 126. In some embodiments, the anisotropic etching process is a dry (e.g., plasma) etching process. Additionally or alternatively, the formation of the gate spacers 126 may also involve chemical oxidation, thermal oxidation, ALD, CVD, and/or other suitable methods. The gate spacers 126 may also be interchangeably referred to as the top spacers.

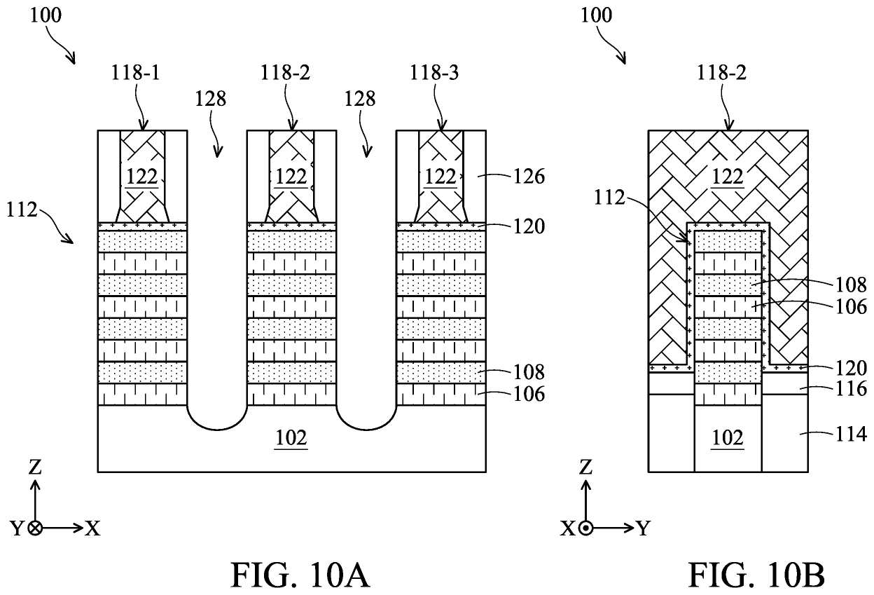

Referring to FIG. 10A and 10B, the fin 112 is recessed to form source/drain trenches 128 in the fin 112 (or passing through the semiconductor layers 106 and 108) exposed by the dummy gate structures 118. More specifically, the source/drain trenches 128 may be formed by performing one or more etching processes to remove portions of the semiconductor layers 106, the semiconductor layers 108, and the substrate 102 that do not vertically overlap or be covered by the dummy gate structures 118 and gate spacers 126. In some embodiments, a single etchant may be used to remove the semiconductor layers 106, the semiconductor layers 108, and the substrate 102, whereas in other embodiments, multiple etchants may be used to perform the etching process. As shown in FIG. 10A, portions of the substrate 102 are etched so that the source/drain trenches 128 each has a concave surface in the substrate 102, and the concave surface is lower than the top surfaces of the isolation features 114 (not shown in FIGS. 10A and 10B).

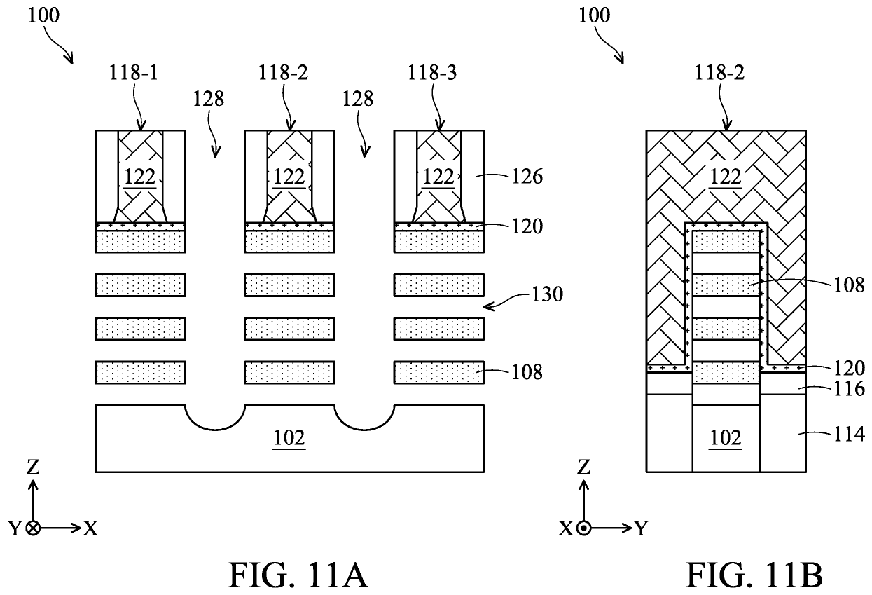

Referring to FIGS. 11A and 11B, semiconductor layers 106 are removed via a selective etching process. More specifically, the selective etching process is performed that selectively etches the semiconductor layers 106 below the gate spacers 124 and the dummy gate structures 118 through the source/drain trenches 128, with minimal (or no) etching of semiconductor layers 108, the gate spacers 124, the isolation features 114, the hard mask layers 116, and the substrate 102, such that gaps 130 are formed between the semiconductor layers 108 in the Z-direction as well as between the semiconductor layers 108 and the substrate 102 the Z-direction, below the gate spacers 124 and the dummy gate structures 118. Therefore, top surfaces and bottom surfaces of the semiconductor layers 108 are exposed, below the gate spacers 124 and the dummy gate structures 118. The etching process is configured to laterally etch (e.g., along the X-direction) the semiconductor layers 106 below the gate spacers 124 and the dummy gate structures 118. The selective etching process is a dry etching process, a wet etching process, other suitable etching process, or combinations thereof.

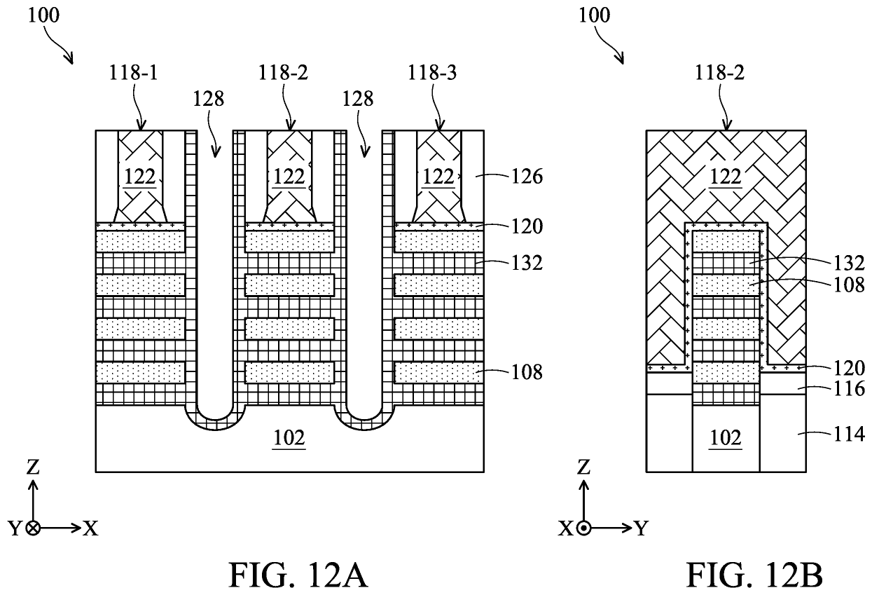

Referring to FIGS. 12A and 12B, a dielectric material 132 is conformally formed into the source/drain trenches 128 and the gaps 130. In some embodiments, a deposition process is performed to form the dielectric material 132 into the source/drain trenches 126 and the gaps 128, such as CVD, PVD, ALD, HDPCVD, MOCVD, RPCVD, PECVD, LPCVD, ALCVD, APCVD, other suitable methods, or combinations thereof. The dielectric material 132 partially fills the source/drain trenches 128 and fully fills the gaps 128, as shown in FIGS. 12A and 12B. More specifically, as shown in FIG. 12A, the dielectric material 132 is conformally formed on top surfaces of the dummy gate structures 118 (specifically, top surfaces of the dummy gate electrodes 122) and the substrate 102 (exposed in the source/drain trenches 128), on sidewalls of the gate spacers 126, and the semiconductor layers 106. Furthermore, the dielectric material 132 is also conformally formed on top surfaces and bottom surfaces of the semiconductor layers 108 exposed in the gaps 130. The deposition process is configured to ensure that the dielectric material 132 fully fills the gaps 130 between the semiconductor layers 108 as well as between the (bottommost) semiconductor layers 108 and the substrate 102 direct under the gate spacers 124 and the dummy gate structures 118.

The dielectric material 132 includes a material that is different than a material of the semiconductor layers 108 and a material of the gate spacers 126 to achieve desired etching selectivity during the etching process. In some embodiments, the dielectric material 132 includes a dielectric material that includes silicon, oxygen, carbon, nitrogen, other suitable material, or combinations thereof (for example, silicon oxide (SiOₓ), silicon nitride (Si₃N₄), silicon carbon (SiC), silicon oxynitride (SiON), silicon oxycarbide (SiOC), silicon carbon nitride (SiCN), silicon oxycarbon nitride (SiOCN)).

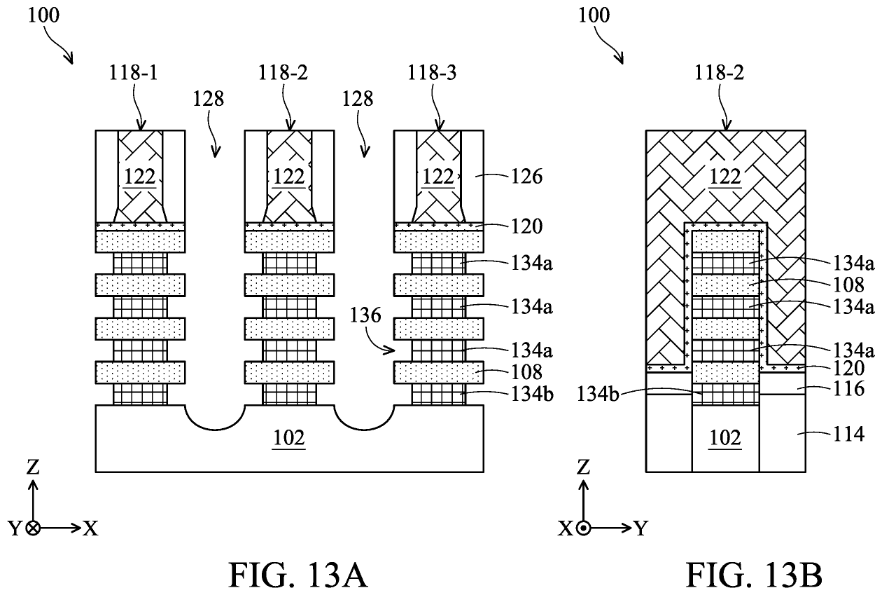

Referring to FIGS. 13A and 13B, one or more etching processes are performed to trim the dielectric material 132 to partially remove the dielectric material 132 to form dielectric layers 134a and 134b (may be collectively referred to as dielectric layer 134). More specifically, one or more etching processes are performed to remove the dielectric material 132 exposed in the source/drain trenches 128, and then remove side portions of the dielectric material 132 between the semiconductor layers 108 as well as between the (bottommost) semiconductor layers 108 and the substrate 102 direct under the gate spacers 124. Therefore, the dielectric layers 134a and 134b are made of the dielectric material 132 and include Si₃N₄, SiO₂, SiC, SiOC, SiON, SiCN, SiOCN, or a combination thereof.

The one or more etching processes are selective etching processes that are performed to selectively etch the dielectric material 132 exposed in the source/drain trenches 128 and the side portions of the dielectric material 132 below the gate spacers 126 through the source/drain trenches 125, with minimal (or no) etching of the dummy gate structures 118, the semiconductor layers 108, the gate spacers 126, the isolation features 114, the hard mask layers 116, and the substrate 102, such that gaps 136 are formed between (the side portions of) the semiconductor layers 108 in the Z-direction as well as between (the side portions of) the semiconductor layers 108 and the substrate 102 the Z-direction, below the gate spacers 126. The etching process is configured to laterally etch (e.g., along the X-direction) the dielectric material 132 below the gate spacers 126. The selective etching process is a dry etching process, a wet etching process, other suitable etching process, or combinations thereof. As such, the dielectric material 132 is trimmed into the dielectric layers 134a between the semiconductor layers 108 and the dielectric layers 134b between the (bottommost) semiconductor layers 108 and the substrate 102 direct under the dummy gate structures 118, as shown in FIG. 13A and 13B.

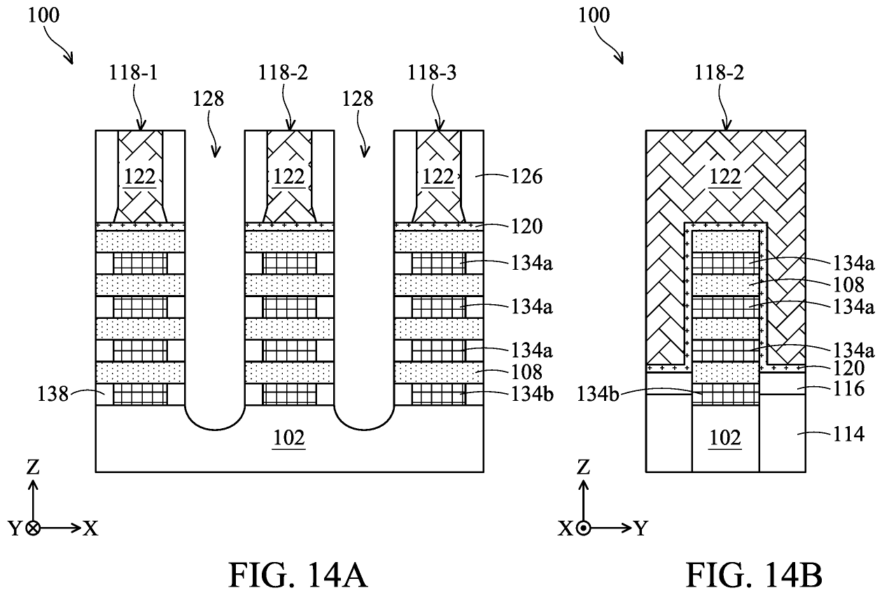

Referring to FIGS. 14A and 14B, inner spacers 138 are formed to fill the gaps 136. The inner spacers 138 are between the semiconductor layers 108 and between the (bottommost) semiconductor layers 108 and the substrate 102 direct under the gate spacers 126. In some embodiments, sidewalls of the inner spacers 138 are aligned to the sidewalls of the gate spacers 126 and the semiconductor layers 108, as shown in FIG. 14A. Furthermore, the inner spacers 138 are on opposite sides of the dielectric layers 134 in the X-direction. In other words, the dielectric layers 134 are between the inner spacers 138 in the X-direction. In order to form the inner spacers 138, a deposition process forms a spacer layer into the source/drain trenches 128 the gaps 136, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 128. The deposition process is configured to ensure that the spacer layer fills the gaps 136 between the semiconductor layers 108 as well as between the semiconductor layer 108 and the substrate 102 under the gate spacers 126. An etching process is then performed that selectively etches the spacer layer to form inner spacers 138 (as shown in FIG. 14A) with minimal (to no) etching of the semiconductor layer 108, the substrate 102, the dummy gate structure 302, and the gate spacers 126. The spacer layer (and thus inner spacers 702) includes a material that is different than a material of the semiconductor layers 108 and a material of the gate spacers 126 to achieve desired etching selectivity during the etching process. In some embodiments, the inner spacers 126 include a dielectric material that includes silicon, oxygen, carbon, nitrogen, other suitable material, or combinations thereof (for example, silicon oxide (SiOₓ), silicon nitride (Si₃N₄), silicon carbon (SiC), silicon oxynitride (SiON), silicon oxycarbide (SiOC), silicon carbon nitride (SiCN), silicon oxycarbon nitride (SiOCN)). In some embodiments, the inner spacers 138 include a low-k dielectric material, such as those described herein.

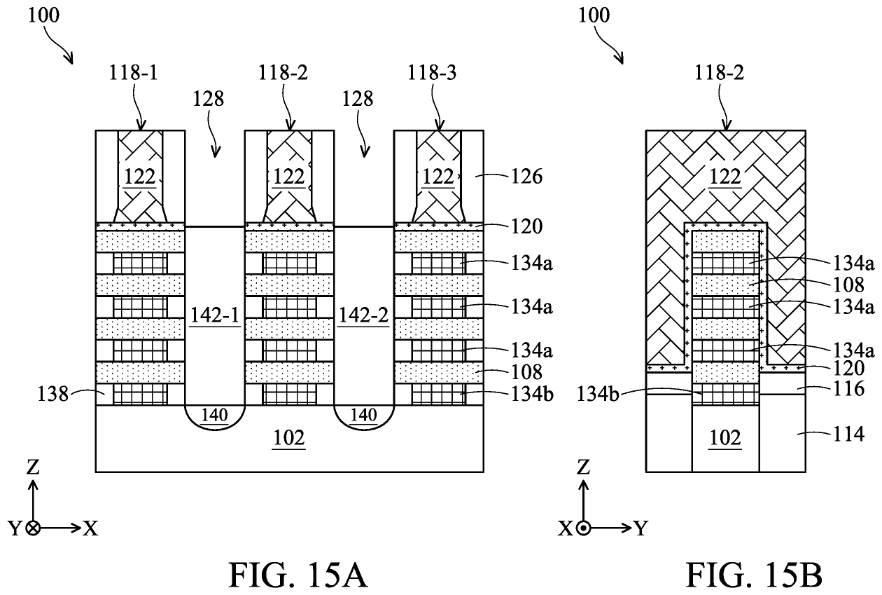

Referring to FIGS. 15A and 15B, silicon layers 140 are formed over the substrate 102 in the source/drain trenches 128. As shown in FIG. 15A, the silicon layers 140 are also formed on opposite sides of the dummy gate structures 118, the semiconductor layers 108, and the dielectric layers 134. In some embodiment, top surfaces of the silicon layers 140 are substantially level with the top surfaces of the substrate 102 and the bottommost surfaces of the dielectric layers 134 (more specifically, the dielectric layers 134b), in the X-Z cross-sectional view, as shown in FIG. 15A. In some embodiments, the top surfaces of the silicon layers 140 are lower than bottommost surfaces of the semiconductors 108. In some embodiment, the silicon layers 140 each has a convex bottom surface due to the concave surfaces of the source/drain trenches 128 discussed above. The silicon layers 140 are made of silicon without dopants. In other word, the silicon layers 140 are un-doped silicon, and thus may be referred to as un-doped silicon layers. As such, the leakage current of the resultant transistors from one source/drain feature to another source/drain feature through the substrate 102 is prevented, thereby improving performances of the resultant transistors. One or more epitaxy processes may be performed to form the silicon layers 140. Epitaxy processes may implement CVD deposition techniques (for example, vapor-phase epitaxy (VPE), UHVCVD, LPCVD, and/or PECVD), molecular beam epitaxy, other suitable SEG processes, or combinations thereof.

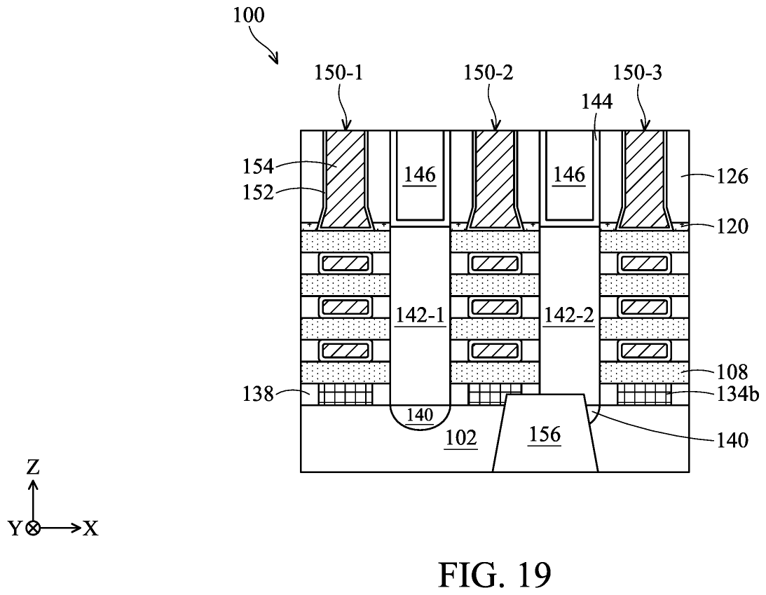

Still referring to FIGS. 15A and 15B, source/drain features 142-1 and 142-2 (may be collectively referred to as source/drain features 142) are formed in the source/drain trenches 126 and over the silicon layers 140 and the substrate 102, so that the source/drain features 142-1 and 142-2 pass through the semiconductor layers 108 and are in the fin 112. The source/drain features 142 are also formed on opposite sides of the dummy gate structures 118 in the X-direction. For example, the source/drain features 142-1 and 142-2 are formed on opposite sides of the dummy gate structure 118-2 in the X-direction, as shown in FIG. 15A. Furthermore, the source/drain features 142 are disposed on opposite sides of the semiconductor layers 108 in the X-direction. The source/drain features 142 are connected to and in contact with the semiconductor layers 108. More specifically, the source/drain features 142 are attached and electrically connected to the semiconductor layers 108 in the X-direction. As shown in FIG. 19A, the source/drain features 142 are also in contact with the inner spacers 138, but are electrically isolated from the inner spacers 138. In some aspects, the inner spacers 138 are disposed between the source/drain features and the dummy gate structure 118 in the X-direction. Furthermore, the silicon layers 140 are between the source/drain features 142 and the substrate 102 in the Z-direction. In some aspect, the silicon layers 140 are under the source/drain features 142 and over the substrate 102. More specifically, the silicon layers 140 are vertically between and in contact with the source/drain features 142 and the substrate 102 in the Z-direction.

In some aspects, the semiconductor layers 108 serve as channels to connect one source/drain feature 142-1 to the other source/drain feature 142-2. Therefore, the semiconductor layers 108 may also be referred to as channels, channel layers, or channel members. In some embodiments, in the X-Z cross-sectional view shown in FIG. 15A, the source/drain features 142-1 and 142-2 may have top surfaces that extend higher than top surfaces of the topmost semiconductor layers 108 (e.g., in the Z-direction), as shown in FIG. 15A. In some embodiments, in the X-Z cross-sectional view shown in FIG. 15A, the source/drain features 142-1 and 142-2 may have the top surfaces that extend higher than bottom surfaces of the dummy interfacial layers 120 (e.g., in the Z-direction). In other embodiments, the top surfaces of the source/drain features 142-1 and 142-2 are substantially level with the top surfaces of the topmost semiconductor layers 108 (i.e., substantially coplanar).

One or more epitaxy processes may be employed to grow the source/drain features 142-1 and 142-2. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 142 may include any suitable semiconductor materials. For example, the source/drain features 142 used for n-type GAA transistors may include epitaxially-grown material selected from a group consisting of silicon phosphide (SiP), silicon carbide (SiC), silicon phosphoric carbide (SiPC), silicon arsenide (SiAs), silicon (Si), or a combination thereof. In some embodiments, the epitaxially-grown material of the source/drain features 142 may be doped with n-type dopants (such as phosphorus, arsenic, other n-type dopant, or combinations thereof) having a doping concentration in a range from about 2×10¹⁹/cm³ to 3×10²¹/cm³. In some embodiments, the source/drain features 142 for n-type GAA transistors may respectively be referred to as n-type source/drain features.

The source/drain features 142 used for p-type GAA transistors may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 142 may be doped with p-type dopants (such as boron, indium, other P-type dopant, or a combination thereof) having a doping concentration in a range from about 1×10¹⁹/cm³ to 6×10²⁰/cm³. In some embodiments, the source/drain features 142 for p-type GAA transistors may respectively be referred to as p-type source/drain features.

The source/drain features 142-1 and 142-2 may also be referred to as source/drain, or source/drain regions. In some embodiments, source/drain feature(s) 142 may refer to a source or a drain, individually or collectively dependent upon the context. The source/drain features 142 may be doped in-situ or ex-situ. One or more annealing processes may be performed to activate the dopants in the source/drain features 142. The annealing processes may include rapid thermal annealing (RTA) and/or laser annealing processes.

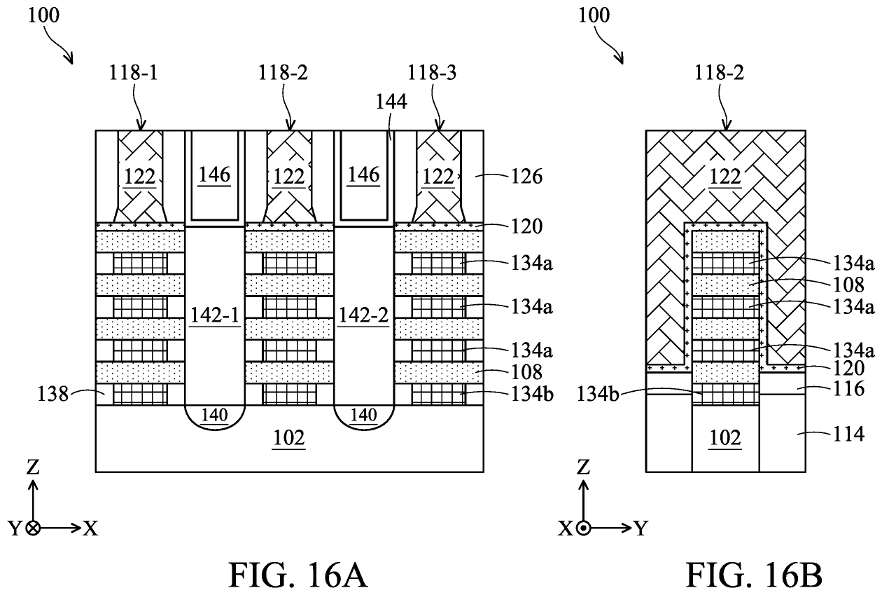

Referring to FIGS. 16A and 16B, a contact etch stop layer (CESL) 144 over the source/drain features 142-1 and 142-2 and an interlayer dielectric (ILD) layer 146 over the CESL 144 are formed to fill the spaces between the gate spacers 126 and in the source/drain trenches 128. Specifically, the CESL 144 is conformally formed on the sidewalls of the gate spacers 126, over the top surfaces of the source/drain features 142-1 and 142-2, as shown in FIGS. 16A. The ILD layer 146 is then formed over the CESL 144 to fill a remaining space between (or inside) the CESL 144, between the gate spacers 126 and in the source/drain trenches 128.

The CESL 144 includes a material that is different than ILD layer 146. The CESL 144 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layer 146 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD 146 may be formed by PECVD (plasma enhanced CVD), FCVD (flowable CVD), or other suitable methods.

Subsequent to the deposition of the CESL 144 and the ILD layer 146, a CMP process and/or other planarization process is performed on the CESL 144 and the ILD layer 146 until the top surfaces of the dummy gate electrodes 122 and the gate spacers 126 are exposed. In some embodiments, portions of the dummy gate electrodes 122 are removed after the planarization process. In some embodiments, the ILD layer 146 is recessed to a level below the top surface of the dummy gate electrode 122, and then an ILD protection layer is formed over the ILD layer 146 to protect the ILD layer 146 from subsequent etching processes. As such, the ILD layer 146 is surrounded by the CESL 144 and the ILD protection layer. In some embodiments, the ILD protection layer includes a material that is the same as or similar to that in the CESL 144. In some other embodiments, the ILD protection layer includes a dielectric material such as Si₃N₄, SiCN, SiOCN, SiOC, a metal oxide such as HrO₂, ZrO₂, hafnium aluminum oxide, hafnium silicate, or other suitable material, and may be formed by CVD, PVD, ALD, or other suitable methods.

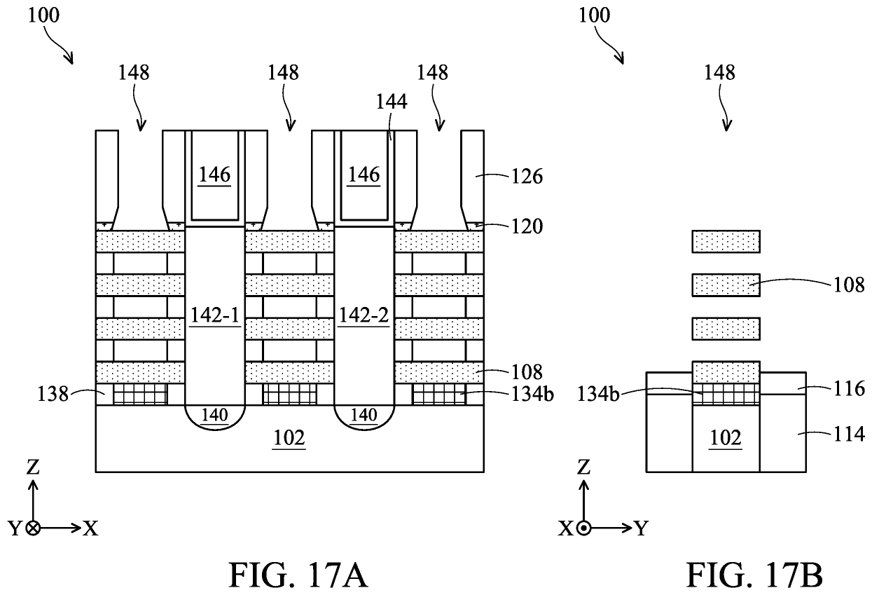

Referring to FIG. 17A and 17B, the dummy gate structures 118 are selectively removed through any suitable lithography and etching processes to form gate trenches 148 (including gate trenches 148-1 to 148-3). In some embodiments, the lithography process may include forming a photoresist layer (resist), exposing the resist to a pattern, performing a post-exposure bake process, and developing the resist to form a masking element, which exposes a region including the dummy gate structures 118. Then, the dummy gate structures 118 are selectively etched through the masking element. The gate spacers 126 may be used as the masking element or a part thereof. Etch selectivity may be achieved by selecting the appropriate etching chemicals, and the dummy gate electrode 122 may be removed without substantially affecting the CESL 144 and the ILD layer 146. The removal of the dummy gate structures 118 creates the gate trenches 148-1 to 148-3, in which the gate trenches 148-1 to 148-3 expose the top surfaces of the fin 112 (specifically, the top surfaces of the topmost semiconductor layers 108).

Still referring to FIGS. 17A and 17B, the dielectric layers 134a are selectively removed through the gate trenches 148, using a wet or dry etching process for example, so that middle portions of the semiconductor layers 108 are exposed in the gate trenches 148 to form nanostructures stacked over each other, which serving as channels, channel layers, or channel members for resultant transistors. In some embodiments, the hard mask layers 116 are also exposed in the gate trenches 148, as shown in FIG. 17B.

It is noted that the isolation features 114 and the hard mask layers 116 are in contact with and on opposite sides of the dielectric layers 134b in the Y-direction, as shown in FIG. 17B. More specifically, the dielectric layers 134b are blocked by the isolation features 114 and hard mask layers 116 in the Y-direction (as shown in FIG. 17B), the inner spacers 138 in the X-direction (as shown in FIG. 17A), and the substrate 102 and the semiconductor layers 108 in the Z-direction, such that the dielectric layers 134b remain after the removal of the dielectric layers 134a.

As such, the semiconductor layers 108 may be referred to as nanostructures. Specifically, the semiconductor layers 108 are stacked over each other in the Z-direction. Such a process may also be referred to as a release process, a channel release process, a wire release process, a nanowire release process, a nanosheet release process, a nanowire formation process, a nanosheet formation process, or a wire formation process.

In some embodiments, the removal of the dielectric layers 134a causes the exposed semiconductor layers 108 to be spaced apart from each other in the vertical direction (e.g., in the Z-direction). The exposed semiconductor layers 108 extend longitudinally in the horizontal direction (e.g., in the X-direction). As shown in FIG. 17A, sidewalls of the inner spacers 138 are also exposed in the gate trenches 148. Furthermore, each of the semiconductor layers 108 connects one source/drain feature 140-1 to the other source/drain feature 140-2 (e.g., shown in FIG. 17A). In some embodiments, thicknesses of the semiconductor layers 108 exposed in the gate trenches 148 may be reduced during the removal of the semiconductor layers 106. In some embodiments, the thickness of the bottommost semiconductor layers 108 is greater than the thickness of the other semiconductor layers 108 after the removal of the dielectric layers 134a due to bottom portions of the bottommost semiconductor layers 108 are blocked by the dielectric layers 134b. In other embodiments, the thickness of the bottommost semiconductor layers 108 is less than the semiconductor layers 108.

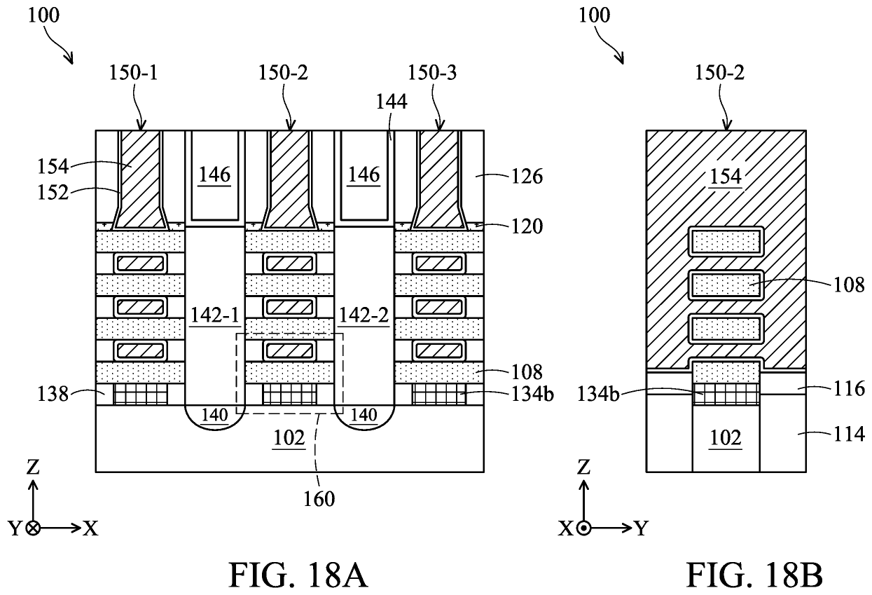

Referring to FIGS. 18A and 18B, gate structures 150 (including gate structures 150-1 to 150-3) are formed in the gate trenches 148 to wrap around the middle portions of the exposed semiconductor layers 108 (the nanostructures). As such, the gate structures 150 replace the dummy gate structures 118. In some embodiments, the gate structures 150 also extend in the Y-direction, as shown in FIG. 18B. As shown in FIG. 18A, the source/drain features 142-1 and 142-2 are disposed on opposite sides of the gate structure 148-2 in the X-direction. The gate structures 148 each includes gate dielectric layer 152 and gate electrode 154 over the gate dielectric layer 152. In some embodiments, the gate dielectric layers 152 are formed to wrap around the semiconductor layers 108 in the gate trenches 148. Additionally, the gate dielectric layers 152 also formed on the sidewalls of the inner spacers 138 and the gate spacers 126.

The gate dielectric layers 152 may include a dielectric material having a dielectric constant greater than a dielectric constant of SiO₂, which is approximately 3.9. For example, the gate dielectric layers 152 may include hafnium oxide (HfO₂), which has a dielectric constant in a range from about 18 to about 40. Alternatively, the gate dielectric layers 152 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layers 152 may be formed by ALD, PVD, CVD, oxidation, and/or other suitable methods.

In some embodiments, the gate structures 150 each may further include interfacial layer formed to wrap around the exposed semiconductor layers 108 before the formation of the gate dielectric layers 152, so that the gate dielectric layers 152 are separated from semiconductor layers 108 by the interfacial layer. In some embodiments, the interfacial layer may include a dielectric material such as silicon oxide (SiO₂), HfSiO, or silicon oxynitride (SiON). The interfacial layer may be formed by chemical oxidation, thermal oxidation, ALD, CVD, and/or other suitable method.

The gate electrodes 154 are formed to fill the remaining spaces of the gate trenches 148, and over the gate dielectric layers 152 in such a way that the gate electrodes 154 wrap around the semiconductor layers 108, the gate dielectric layers 152, and the interfacial layers (if present). The gate electrodes 154 each may include a single layer or alternatively a multi-layer structure. In some embodiments, the gate electrodes 154 each may include a capping layer, a barrier layer, work function metal layers, and a fill material.

The capping layer may be formed adjacent to the gate dielectric layers 152 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The gate electrodes 154 may each has single or multiple work function metal materials. In some embodiments, the gate electrodes 154 may each has n-type work function metal layers for n-type GAA transistors and p-type work function metal layers for p-type GAA transistors. More specifically, the gate electrodes 154 may each has n-type work function metal layers between the source/drain features 142 with n-type dopant for n-type GAA transistors and p-type work function metal layers between the source/drain features 142 with p-type dopant for p-type GAA transistors, in accordance with some embodiments of the present disclosure.

In some embodiment, the n-type work function metal layer may be a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer.

In some embodiments, the p-type work function metal layer may be a material such as TiN, TaN, Ru, Mo, Al, WN, ZrSi₂, MoSi₂, TaSi₂, NiSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the P-type work function metal layer may be deposited using a deposition process such as ALD, CVD, or the like, although any suitable deposition process may be used.

Therefore, the workpiece 100 (or the semiconductor structure 100) with GAA transistors/devices are provided. As shown in FIG. 18A and 18B, the gate structures 150 are also formed over the dielectric layers 134b. More specifically, the gate structures 150 are separated from the substrate 102 by the dielectric layers 134b and the bottommost semiconductor layers 108. In some embodiments, the dielectric layers 134b are under the gate structures 150, and between and in contact with the (bottommost) semiconductor layers 108 and the substrate 102 in the Z-direction to further separate the gate structures 150 from the substrate 102. Therefore, the parasitic capacitance between the gate structures 150 and the substrate 102 are reduced due to the gate structures 150 and the substrate 102 are farther separated, thereby improving the performance of the GAA transistors.

Furthermore, the dielectric layers 134b have a thickness T in the Z-direction. In some embodiments, the thickness T of the dielectric layers 134b in the Z-direction is in a range from about 3 nm to about 10 nm. If the thickness T of the dielectric layers 134b in the Z-direction are too small (the thickness T is less than about 3 nm), the parasitic capacitance between the gate structures 150 and the substrate 102 cannot be significantly reduced. If the thickness T of the dielectric layers 134b in the Z-direction are too large (the thickness T is greater than about 10 nm, the process stability may be impacted. Furthermore, the dielectric layers 134b is formed between the inner spacers 138 in the X-direction. Such structure is more applicable to the existing processes for GAA transistors.

FIG. 19 is an X-Z cross-sectional view of the workpiece 100 at the fabrication stage, in accordance with some alternative embodiments of the present disclosure. The structure shown in FIG. 19 is similar to the structure shown in FIG. 18A discussed above, except that a back-side via 156 is further formed under the source/drain features 142 and the gate structures 150. More specifically, the back-side via 156 is formed passing through the substrate 102 (from the back-side of the substrate 102) and electrically connected to one of the source/drain features 142 (i.e., the source/drain features 142-2), as shown in FIG. 19.

Furthermore, the back-side via 156 is in contact with the dielectric layer 134b under the gate structures 150-2. In other words, a top surface of the back-side via 156 is in contact with the dielectric layer 134b and the source/drain feature 142-2. In some embodiments, the dielectric layer 134b is also in contact with a sidewall of the back-side via 156, as shown in FIG. 19. Such structure shown in FIG. 19 means that the back-side via 156 can be formed not to align with the source/drain feature 142-2 due to the dielectric layer 134b separate the gate structure 150-2 from the substrate 102. The back-side via 156 is electrically isolated from the gate structure 150-2. Therefore, the back-side via 156 can be formed larger and does not need to be formed to align exactly with the source/drain feature 142-2. Therefore, in the case of the back-side via 156 formed in the back-side of the workpiece 100 in the present embodiments, the process window is increased and the resistance of the back-side via 156 is reduced.

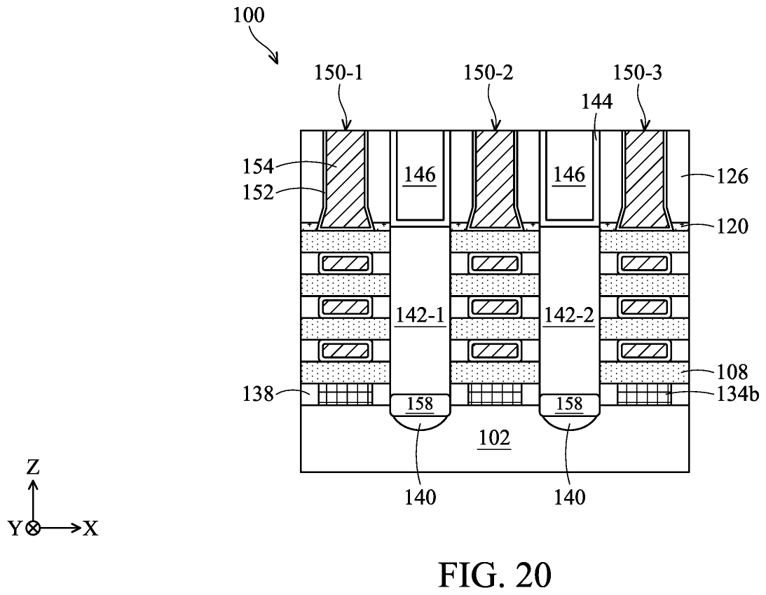

FIG. 20 is an X-Z cross-sectional view of the workpiece 100 at the fabrication stage, in accordance with some alternative embodiments of the present disclosure. The structure shown in FIG. 20 is similar to the structure shown in FIG. 18A discussed above, except that bottom dielectric layers 158 are formed between the source/drain features 142 and the silicon layers 140 in the Z-direction. More specifically, after the formation of the silicon layers 140 and before the formation of the source/drain features 142, the bottom dielectric layers 158 are formed over the silicon layers 140.

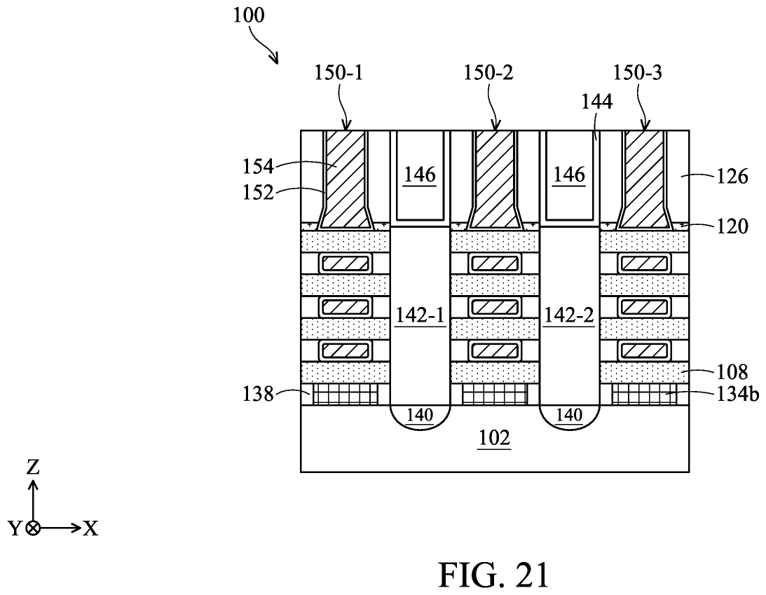

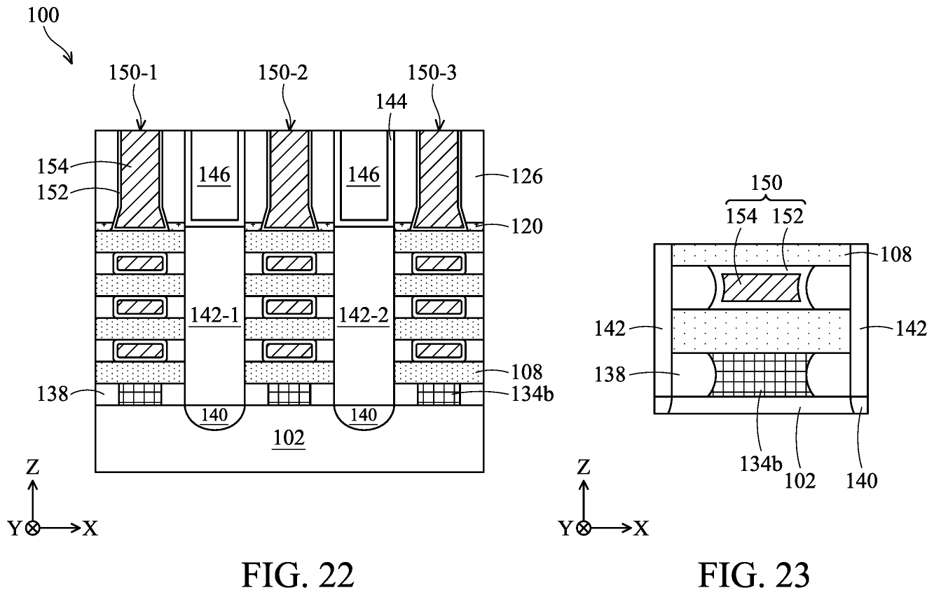

In some embodiment, the bottom dielectric layers 158 are between and in contact with sidewalls of the inner spacers 138, in the X-Z cross-sectional view, as shown in FIG. 20. In order to form the bottom dielectric layers 158, a dielectric material is conformally formed over the silicon layers 140, and on the sidewalls of the gate spacers 126, the inner spacers 138, and the semiconductor layers 108 by a deposition process, such as CVD, PVD, ALD, HDPCVD, MOCVD, RPCVD, PECVD, LPCVD, ALCVD, APCVD, other suitable methods, or combinations thereof. An etching process is then performed that etches portions of the dielectric material on the sidewalls of the gate spacers 126, the inner spacers 138, and the semiconductor layers 108 to form the bottom dielectric layers 158 over the silicon layers 140, as shown in FIGS. 19. In some embodiments, the dielectric material may include Si₃N₄, SiO₂, SiC, SiOC, SiON, SiCN, SiOCN, other suitable material(s), or combinations thereof FIGS. 21 and 22 are X-Z cross-sectional views of the workpiece 100 at the fabrication stage, in accordance with some alternative embodiments of the present disclosure. The structures shown in FIGS. 21 and 22 are similar to the structure shown in FIG. 18A discussed above, except that c More specifically, a width of the dielectric layers 134b in the X-direction is greater than a width of the gate structures 150 in the X-direction, as shown in FIG. 21. In some embodiments, the width of the dielectric layers 134b in the X-direction is less than the width of the gate structures 150 in the X-direction, as shown in FIG. 22. Therefore, the sidewalls of the dielectric layers 134b are offset from sidewalls of the gate structures 150 in the X-direction.

FIG. 23 is a partial enlarged cross-sectional view of the workpiece 100 at the fabrication stage in a dashed box 160 of FIG. 18A, in accordance with some alternative embodiments of the present disclosure. Referring back to FIG. 18A, each of the dielectric layers 134b has a rectangle shape in the X-Z cross-sectional view, in accordance with some embodiments. More specifically, each of the dielectric layers 134b has vertical sidewalls in the X-Z cross-sectional view. As shown in FIG. 23, each of the dielectric layers 134b includes concave sidewalls in contact with the inner spacers 138 in the X-Z cross-sectional view. Such concave sidewalls of the dielectric layers 134b may be formed in the fabrication stage shown in FIG. 13A. Furthermore, the inner spacers 138 includes convex sidewalls due to the concave sidewalls of the dielectric layers 134b, as shown in FIG. 23. In some embodiments, the gate structures 150 also includes concave sidewalls in contact with the inner spacers 138.

The embodiments disclosed herein relate to semiconductor structures and their manufacturing methods, and more particularly to methods and semiconductor structures including GAA transistors with dielectric layer under a gate structure, and between nanostructures and substrate. Furthermore, the present embodiments provide one or more of the following advantages. The dielectric layer under a gate structure, and between the nanostructures and the substrate reduce parasitic capacitance between the gate structure and the substrate. Therefore, the performance of the GAA transistor is improved. Furthermore, dielectric layer under a gate structure, and between the nanostructures and the substrate increase the process window for forming a back-side via.

Thus, one of the embodiments of the present disclosure describes a semiconductor structure that includes a substrate, nanostructures, a dielectric layer, source/drain features, a gate structure, and inner spacers. The nanostructures are over the substrate and spaced apart from each other in a Z-direction. The dielectric layer is between and in contact with the nanostructures and the substrate in the Z-direction. The source/drain features are electrically connected to and on opposite sides of the nanostructures in an X-direction. The gate structure extends in a Y-direction and wraps around the nanostructures. The inner spacers are between the nanostructures and the substrate in the Z-direction. The inner spacers are on opposite sides of the dielectric layer in the X-direction.

In some embodiments, the hard mask layers are in contact with a bottommost nanostructure of the nanostructures and the dielectric layer.

In some embodiments, the hard mask layers comprise high-k material.

In some embodiments, the semiconductor structure further includes a back-side via passing through the substrate. A top surface of the back-side via is in contact with the dielectric layer and one of the source/drain features.

In some embodiments, a thickness of the dielectric layer in the Z-direction is in a range from about 3 nm to about 10 nm.

In some embodiments, a width of the dielectric layer in the X-direction is greater than a width of the gate structure in the X-direction.

In some embodiments, a width of the dielectric layer in the X-direction is less than a width of the gate structure in the X-direction.

In some embodiments, the dielectric layer comprises concave sidewalls in contact with the inner spacers.

In some embodiments, the semiconductor structure further includes un-doped silicon layers between the source/drain features and the substrate. bottom dielectric layers between the source/drain features and the un-doped silicon layers.

In some embodiments, the semiconductor structure further includes

In another of the embodiments, discussed is a semiconductor structure including a substrate, nanostructures, a gate structure, source/drain features, inner spacers, and a dielectric layer. The nanostructures are over the substrate and spaced apart from each other in a Z-direction. The gate structure extends in a Y-direction and wraps around the nanostructures. The source/drain features are on opposite sides of the gate structure in an X-direction and attached to the nanostructures in the X-direction. The inner spacers are between the nanostructures and the substrate in the Z-direction. The dielectric layer under the nanostructures and the gate structure, over the substrate, and between the inner spacers the X-direction.

In some embodiments, the semiconductor structure further includes isolation features on opposite sides of the dielectric layer in the Y-direction and hard mask layers over the isolation features. The hard mask layers are in contact with the dielectric layer in the Y-direction.

In some embodiments, the semiconductor structure further includes a back-side via under the source/drain features and the gate structure. The dielectric layer is in contact with a sidewall of the back-side via.

In some embodiments, sidewalls of the dielectric layer are offset from sidewalls of the gate structure in the X-direction.

In some embodiments, the dielectric layer comprises Si₃N₄, SiO₂, SiC, SiOC, SiON, SiCN, SiOCN, or a combination thereof.

In some embodiments, a thickness of a bottommost nanostructures of the nanostructures is less than a thickness of the other nanostructures.

In yet another of the embodiments, discussed is a method for manufacturing a semiconductor structure including forming a fin over a substrate. The fin includes first semiconductor layers and second semiconductor layers alternating stacked in a Z-direction. The method further includes forming a dummy gate structure extending in a Y-direction and over the fin, forming source/drain trenches in the fin and on opposite sides of the dummy gate structures in the X-direction, removing the first semiconductor layers through the source/drain trenches, forming a first dielectric layer between the second semiconductor layers and the substrate and forming second dielectric layers between the second semiconductor layers, forming inner spacers between the second semiconductor layers in the Z-direction, forming source/drain features in the source/drain trenches, and replacing the dummy gate structure and the second dielectric layers with a gate structure wrapping around the second semiconductor layers. The first dielectric layer is between the inner spacers in the X-direction.

In some embodiments, the method further includes forming isolation features on opposite sides of the fin in the Y-direction and forming hard mask layers over the isolation features. The isolation features and the hard mask layers are in contact with a bottommost first semiconductor layer of the first semiconductor layers.

In some embodiments, the method further includes forming dielectric material wrapping around the second semiconductor layers and removing the dielectric material exposed in the source/drain trenches to form the first dielectric layer and the second dielectric layers.

In some embodiments, the method further includes forming a back-side via passing through the substrate and electrically connected to one of the source/drain features. The back-side via is in contact with the first dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
nanostructures over the substrate and spaced apart from each other in a Z-direction;
a dielectric layer between and in contact with the nanostructures and the substrate in the Z-direction;
source/drain features electrically connected to and on opposite sides of the nanostructures in an X-direction;
a gate structure extending in a Y-direction and wrapping around the nanostructures; and
inner spacers between the nanostructures and the substrate in the Z-direction, wherein the inner spacers are on opposite sides of the dielectric layer in the X-direction.

2. The semiconductor structure of claim 1, further comprising:
isolation features on opposite sides of the nanostructures in the Y-direction; and
hard mask layers over the isolation features, wherein the hard mask layers are in contact with a bottommost nanostructure of the nanostructures and the dielectric layer.

3. The semiconductor structure of claim 2, wherein the hard mask layers comprise high-k material.

4. The semiconductor structure of claim 1, further comprising:
a back-side via passing through the substrate, wherein a top surface of the back-side via is in contact with the dielectric layer and one of the source/drain features.

5. The semiconductor structure of claim 1, wherein a thickness of the dielectric layer in the Z-direction is in a range from about 3 nm to about 10 nm.

6. The semiconductor structure of claim 1, wherein a width of the dielectric layer in the X-direction is greater than a width of the gate structure in the X-direction.

7. The semiconductor structure of claim 1, wherein a width of the dielectric layer in the X-direction is less than a width of the gate structure in the X-direction.

8. The semiconductor structure of claim 1, wherein the dielectric layer comprises concave sidewalls in contact with the inner spacers.

9. The semiconductor structure of claim 1, further comprising:
un-doped silicon layers between the source/drain features and the substrate.

10. The semiconductor structure of claim 9, further comprising:
bottom dielectric layers between the source/drain features and the un-doped silicon layers.

11. A semiconductor structure, comprising:
a substrate;
nanostructures over the substrate and spaced apart from each other in a Z-direction;
a gate structure extending in a Y-direction and wrapping around the nanostructures;
source/drain features on opposite sides of the gate structure in an X-direction and attached to the nanostructures in the X-direction;
inner spacers between the nanostructures and the substrate in the Z-direction; and
a dielectric layer under the nanostructures and the gate structure, over the substrate, and between the inner spacers the X-direction.

12. The semiconductor structure of claim 11, further comprising:
isolation features on opposite sides of the dielectric layer in the Y-direction; and
hard mask layers over the isolation features, wherein the hard mask layers are in contact with the dielectric layer in the Y-direction.

13. The semiconductor structure of claim 11, further comprising:
a back-side via under the source/drain features and the gate structure, wherein the dielectric layer is in contact with a sidewall of the back-side via.

14. The semiconductor structure of claim 11, wherein sidewalls of the dielectric layer are offset from sidewalls of the gate structure in the X-direction.

15. The semiconductor structure of claim 11, wherein the dielectric layer comprises Si₃N₄, SiO₂, SiC, SiOC, SiON, SiCN, SiOCN, or a combination thereof.

16. The semiconductor structure of claim 11, wherein a thickness of a bottommost nanostructures of the nanostructures is less than a thickness of the other nanostructures.

17. A method for manufacturing a semiconductor structure, comprising:
forming a fin over a substrate, wherein the fin comprises first semiconductor layers and second semiconductor layers alternating stacked in a Z-direction;
forming a dummy gate structure extending in a Y-direction and over the fin;
forming source/drain trenches in the fin and on opposite sides of the dummy gate structures in the X-direction;
removing the first semiconductor layers through the source/drain trenches;
forming a first dielectric layer between the second semiconductor layers and the substrate and forming second dielectric layers between the second semiconductor layers;
forming inner spacers between the second semiconductor layers in the Z-direction, wherein the first dielectric layer is between the inner spacers in the X-direction;
forming source/drain features in the source/drain trenches; and
replacing the dummy gate structure and the second dielectric layers with a gate structure wrapping around the second semiconductor layers.

18. The method of claim 17, further comprising:
forming isolation features on opposite sides of the fin in the Y-direction; and
forming hard mask layers over the isolation features, wherein the isolation features and the hard mask layers are in contact with a bottommost first semiconductor layer of the first semiconductor layers.

19. The method of claim 17, further comprising:
forming dielectric material wrapping around the second semiconductor layers; and
removing the dielectric material exposed in the source/drain trenches to form the first dielectric layer and the second dielectric layers.

20. The method of claim 17, further comprising:
forming a back-side via passing through the substrate and electrically connected to one of the source/drain features, wherein the back-side via is in contact with the first dielectric layer.
